(19) United States
(12) Patent Application Publication
(10) Pub. No.: US 2002/0105348 A1
(43) Pub. Date: Aug. 8, 2002

(54) Electronically measuring pin-to-pad alignment using resistive pads

(76) Inventor: Griffith L. Resor III, Acton, MA (US)

Correspondence Address: Legal Department, Teradyne, Inc., 321 Harrison Avenue, Boston, MA, 02118, US

(21) Appl. No.: 09/735,247

(22) Filed: Dec. 12, 2000

(51) Int. Cl. G01R 31/02

(52) U.S. Cl. 324/758

(57) ABSTRACT

A technique for monitoring the alignment of groups of spring-loaded pins extending from a test head of an automatic component tester with conductive pads for receiving the spring-loaded pins includes a printed circuit board having an array of resistive pads. The resistive pads have substantially uniform sheet resistivity across their surfaces and have at least one electrode extending therefrom. The printed circuit board is placed against the spring-loaded pins in place of the conductive pads, so that the pins make contact with the resistive pads. When a pin makes contact with a pad, it forms an impedance with each electrode of the pad. By measuring each impedance, the location of the pin relative to the pad can be determined. Impedance measurements can be conducted at high speed under computer control. In addition, measurement results can be stored and analyzed for diagnosing and predicting faults due to misalignments of pins to pads.

This invention relates generally to automatic test equipment for electronics. More particularly, this invention relates to monitoring the alignment of pins used to make contact with conductive pads to form connections between different portions of an automatic test system.

### BACKGROUND OF THE INVENTION

Automatic test equipment (ATE) plays a significant role in the manufacture of semiconductor devices. Manufacturers generally use automatic test equipment—or “testers”—to verify the operation of semiconductor devices at the wafer and packaged device stages of semiconductor manufacturing processes.

To accommodate the testing of different types of devices, testers generally employ specialized device interface boards or “DIBs.” A DIB maps interface nodes of a tester to interface nodes of a device under test, or “DUT.” Different DIBs are generally provided for testing different types of DUTs.

The input and output nodes of a tester generally connect to a DIB via conductive, spring-loaded pins. The spring-loaded pins extend from the tester, and make contact with conductive pads on the DIB. Conductive traces within the DIB convey signals between the tester and the DUT, and allow the tester to exercise the DUT. Once a DIB is placed against the tester, the spring-loaded pins are compressed against the pads of the DIB, and connections are established between the tester and the DUT.

As devices become more complex, more spring-loaded pins are needed to thoroughly test the devices. As devices become smaller, the pins must be spaced more closely together. Consequently, testers typically employ extremely small spring-loaded pins. For example, the Catalyst™ tester manufactured by Teradyne, Inc., of Boston, Mass. uses spring-loaded pins with diameters of only 0.635 mm (25 mils). The conductive pads on the DIBs with which these pins make contact have widths of only 1.524 mm (60 mils). Plans are already in place for shrinking pad widths to only 1.143 mm (45 mils).

Maintaining alignment between pins and pads having such small diameters presents a significant challenge. Misalignments arise from a number of sources, including coarse misalignments between the DIB and the tester, misalignment of the pins within the tester, bent pins, and dimensional instabilities of the materials that constitute the DIB and the tester.

Successful testing of components relies on pins making good contact with pads. Accordingly, procedures have been developed to verify pin-to-pad alignment. One common method involves replacing the DIB with a transparent board or sheet. Circular patterns are inscribed on one surface of the board in the areas where the conductive pads are normally found on the DIB. Using a hand-held magnifier, a human operator manually inspects positions of the pins with respect to the circular patterns. Properly aligned pins fall within the circumference of the corresponding circular patterns on the transparent board.

This technique suffers from a number of drawbacks. Because it is manual, this technique takes a great deal of time to perform, particularly when a tester has a large number of pins. Results can be inconsistent and suffer from human error. Perhaps more importantly, the manual process does not provide quantitative information about pin-to-pad alignment. Unless great effort is expended, no data is collected about the alignment of pins to pads, or about changes in pin-to-pad alignment between different uses or over time. Because the misalignment of pins and pads will likely present a significant obstacle to future testing, we believe that a quantitative method of monitoring pin-to-pad alignment will be crucial to the success of ATE systems.

### SUMMARY OF THE INVENTION

With the foregoing background in mind, it is an object of the invention to quantitatively monitor the alignment of pins with respect to pads in automatic test systems.

It is another object of the invention to monitor the alignment of pins and pads at much higher speeds than current methods permit.

To achieve the foregoing objects and other objectives and advantages, a system for monitoring the alignment of pins with respect to conductive pads in an automatic test system includes an array of resistive pads. The array of resistive pads is physically positioned in place of the conductive pads, so that the resistive pads occupy the space normally occupied by the conductive pads. The array of resistive pads has a layout that substantially matches the layout of the conductive pads that the resistive pads replace. Each resistive pad has an electrode extending from a portion of the resistive pad. When a pin makes contact with a resistive pad, the pin forms an impedance with the electrode. The location of the pin relative to the electrode, and thus relative to the pad, is then determined from the impedance. Impedance measurements can be repeated at high speed for each resistive pad, thus allowing high-speed monitoring of pin-to-pad alignment.

### BRIEF DESCRIPTION OF THE DRAWINGS

Additional objects, advantages, and novel features of the invention will become apparent from a consideration of the ensuing description and drawings, in which

FIG. 1 is a top, plan view of one resistive pad as provided in accordance with the invention;

FIG. 2 is a simplified, equivalent schematic of the resistive pad of FIG. 1;

FIG. 3 is simplified schematic of an array of resistive pads for monitoring pin-to-pad alignment according to the invention;

FIG. 4 is a flowchart showing a process for manufacturing a diagnostic circuit board including an array of resistive pads; and

FIGS. 5a and 5b are top, plan views of the diagnostic circuit board, as viewed during different steps of the manufacturing process shown in FIG. 4.

### DESCRIPTION OF THE PREFERRED EMBODIMENT

Structure and Equivalent Circuit of Resistive Pad

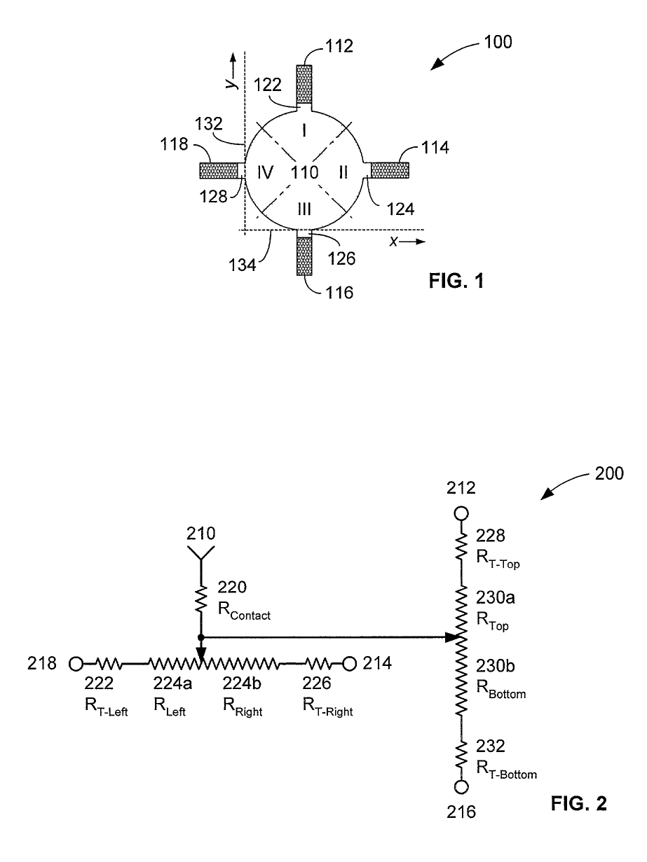

FIG. 1 illustrates a top view of a single resistive pad 100 constructed in accordance with the invention. The resistive pad 100 is preferably fabricated on an outer surface of a printed circuit board using a thin-film resistive material, such as Ohmega-Ply® material from Ohmega Technologies, Inc., of Culver City, Calif.

As shown in FIG. 1, the resistive pad 100 includes a resistive body 110. The resistive body 110 has a substantially uniform sheet resistivity across its surface and can be regarded as including four immediately adjacent, substantially even quadrants, numbered I-IV. Electrodes 112, 114, 116, and 118 respectively form electrical connections with, and extend from, the first through fourth quadrants of the resistive body 110. Tabs 122, 124, 126, and 128 extend outwardly from the resistive body 110, to form connections with the electrodes 112, 114, 116, and 118, respectively.

When a conductive pin makes contact with any point along the surface of the resistive body 110, it forms an impedance with each of the electrodes 112, 114, 116, and 118. These impedances can be measured to ascertain the location of the pin along the surface of the resistive body 110, where the pin makes contact with the resistive body 110.

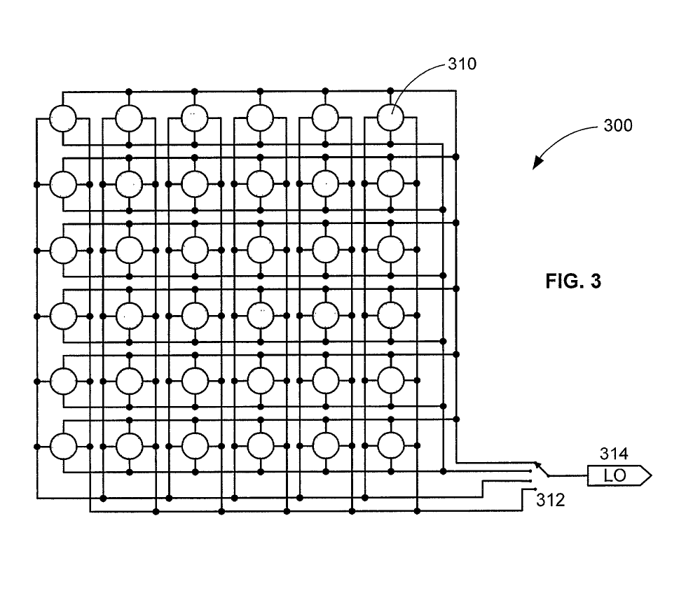

FIG. 2 is a simplified, equivalent schematic 200 of the resistive pad 100. Terminals 212, 214, 216, and 218 respectively represent the electrodes 112, 114, 116, and 118 of FIG. 1. As indicated, a conductive pin 210 makes contact with a resistive pad 100 through a corresponding contact resistance 220.

The impedances formed between the pin 210 and the electrodes 112, 114, 116, and 118 are complicated functions. They include terms related to the geometry of the pad 100, the geometry of the pin where the pin makes contact with the pad, and the point along the surface of the pad where contact is made. To a first-order approximation, however, these impedances can be modeled as simple potentiometers or “slide-wires.” In particular, a horizontal slide-wire is formed among the pin 210 and the electrodes 214 and 218 of quadrants II and IV, and a vertical slide-wire is formed among the pin 210 and the electrodes 212 and 216 of quadrants I and III.

As shown in FIG. 2, the horizontal slide-wire formed between the pin 210 and the electrodes 214 and 218 includes five components:

1. A contact resistance 220 (R_{contact}).

2. An impedance 222 (R_{T-Left}) corresponding to the tab 128;

3. An impedance 224a (R_{Left}) corresponding to the path between the pin 210 and the tab 128;

4. An impedance 224b (R_{Right}) corresponding to the path between the pin 210 and the tab 124; and

5. An impedance 226 (R_{T-Right}) corresponding to the tab 124.

Using standard Ohmega-Ply® material with a surface resistivity of 25-ohms/square, the contact resistance 220 between a 25-mil diameter, gold-plated pin and a pad has been empirically measured to be approximately 52-ohms. We have found that contact resistance is substantially constant over time and over multiple contacts between a pin and a pad. Assuming a round pad with a diameter of 1.524 mm (60 mils), the resistance across the pad can be calculated to be approximately 30-ohms. The impedances of the tabs 222 and 226 have been empirically measured to be approximately 5-ohms each.

Given these values, the impedance R_{Left} can then be determined as follows:

$$\begin{matrix}{Z}_{1} = {R}_{Contact} + {R}_{Left} + {R}_{TLeft} , or \\ {R}_{Left} = {Z}_{1} - 57 ohms ,\end{matrix} \qquad ( EQ . 1 )$$

where Z₁ is a measured impedance between the pin 210 and the terminal 218. Similarly, the impedance R_{Right} can be expressed as

R_{Right}=Z₂−57ohms, (EQ.2)

where Z₂ is a measured impedance between the pin 210 and the terminal 214.

With these resistances known, the horizontal distance of the pin from a left edge 132 of the resistive body 110 can be expressed in terms of R_{Left}:

$${D}_{H1} = W * \frac{{R}_{Left}}{{R}_{TotH}} , \qquad ( EQ . 3 )$$

where W is the width of the pad (1.524 mm, or 60 mils) and R_{TotH} is the horizontal resistance across the resistive body 110 (i.e., 30-ohms). This same distance can also be expressed in terms of R_{Right}:

$${D}_{H2} = W ( 1 - \frac{{R}_{Right}}{{R}_{TotH}} ) . \qquad ( EQ . 4 )$$

Either of the expressions D_{H1} and D_{H2} can separately determine the horizontal position of the pin relative to the pad. We have recognized, however, that there is an advantage to combining the two expressions. We have recognized that the precise dimensions of the tabs 124 and 128 can vary slightly, and that these variations can introduce errors in determining the position of the pin relative to the pad. We have found, however, that the average value of D_{H1} and D_{H2} is insensitive to variations in tab dimensions, as long as the variations are symmetrical with respect to the center of pad. Therefore, the distance of the pin from the left edge 132 of the pad is preferably expressed as follows:

$${D}_{H} = \frac{{D}_{H1} + {D}_{H2}}{2} . \qquad ( EQ . 5 )$$

The relationships developed above apply analogously to the vertical slide-wire formed among the pin 210 and the terminals 212 and 216 of quadrants I and III. Like the horizontal slide wire, the vertical slide-wire includes five components:

1. A contact resistance 220 (R_{Contact}).

2. An impedance 228 (R_{T-Top}) corresponding to the tab 122;

3. An impedance 230a (R_{Top}) corresponding to the path between the pin 210 and the tab 122;

4. An impedance 230b (R_{Bottom}) corresponding to the path between the pin 210 and the tab 126; and

5. An impedance 232 (R_{T-Bottom}) corresponding to the tab 126.

The impedances RT_{Top} and R_{Bottom} are determined as follows:

$$\begin{matrix}{D}_{V1} = H * \frac{{R}_{Bottom}}{{R}_{TotV}} & ( EQ . 8 ) \\ {D}_{V2} = H ( 1 - \frac{{R}_{Top}}{{R}_{TotV}} ) , & ( EQ . 9 )\end{matrix}$$

where Z₃ is an impedance measured between the pin 210 and the terminal 212, and Z₄ is an impedance measured between the pin 210 and the terminal 216.

With these resistances known, the vertical distance between the pin and a bottom edge 134 of the resistive body 110 can be expressed using either of the following equations:

$$\begin{matrix}{R}_{Top} = {Z}_{3} - 57 ohms , and & ( EQ . 6 ) \\ {R}_{Bottom} = {Z}_{4} - 57 ohms & ( EQ . 7 )\end{matrix}$$

where H is the height of the pad (1.524 mm, or 60 mils) and R_{TotV} is the vertical resistance across the pad (i.e., 30-ohms). The distance of the pin from the bottom edge 134 of the resistive pad is preferably expressed as the average of these values:

$${D}_{V} = \frac{{D}_{V1} + {D}_{V2}}{2} . \qquad ( EQ . 10 )$$

With the horizontal and vertical distances D_{H} and D_{V} known, the location of the pin relative to the pad is simply the point that is both a distance D_{H} to the right of the left edge 132 and a distance Dᵥ up from the bottom edge 134 of the resistive body 110.

Diagnostic Circuit Board

To monitor the alignment of pins to pads in an automatic test system, an array of resistive pads 100 is fabricated on a diagnostic circuit board. The array of resistive pads forms a geometrical pattern that substantially matches the geometrical pattern of conductive pads normally found on the DIB. To monitor pin-to-pad alignment, the diagnostic circuit board is installed in place of the DIB so that the resistive pads occupy the locations normally occupied by the conductive pads of the DIB. The resistive pads then make contact with the pins extending from the tester, just as the conductive pads on the DIB make contact with the pins of the tester during normal operation.

FIG. 3 schematically illustrates an exemplary array 300 of resistive pads 310. Each resistive pad 310 is preferably identical to the resistive pad 110 of FIG. 1. As shown in FIG. 3, the top electrode 1 12, bottom electrode 1 16, left electrode 118, and right electrode 1 14 of each resistive pad 310 respectively connects the top, bottom, left, and right electrode of each of the other resistive pads 310 in the array 300.

A selector 312 is coupled to the resistive pads 310 and selects from among the top, bottom, left, and right electrodes. The selector 312 has four inputs: a first input connected to all of the top electrodes 112; a second input connected to all of the bottom electrodes 116; a third input connected to all of the left electrodes 118, and a fourth input connected to all of the right electrodes 114. The selector 312 selects one of these four inputs to conduct the input to an output 314 (“LO”).

Conventional testers generally include independently controllable relays connected in series with their pins. When these relays are opened, the pins effectively “float,” i.e., they form no electrical connections within the tester. Conventional testers also include a switching matrix connected to the pins and analog instruments that can be connected to each pin through the switching matrix. By properly configuring the switching matrix and the series-connected relays, a terminal of an analog instrument can be connected to one and only one pin. Another terminal of the analog instrument can be connected to the output 314 of the selector 312. With the analog instrument configured for measuring impedance, separate impedance measurements can then be made for each pin. By varying the position of the selector 312, all four impedances Z₁-Z₄ described above can be measured for each pin-to-pad connection.

The exact method employed for measuring impedance can be varied substantially within the scope of the invention. In the preferred embodiment, an accurate fixed current, for example 1 mA, is sourced into one pin at a time, while the other pins float. A voltmeter is connected between the pin sourcing the current and the output 314 of the selector 312. The output of the selector is coupled to ground. For each position of the selector 312, the voltmeter measures the voltage induced between the pin and the output 314 of the selector 312. Each impedance is then computed as the respective measured voltage divided by the sourced current. From the measured impedances, the alignment of pins to pads for each pad 310 in the array 300 is then determined, using the equations derived above.

Manufacturing Process

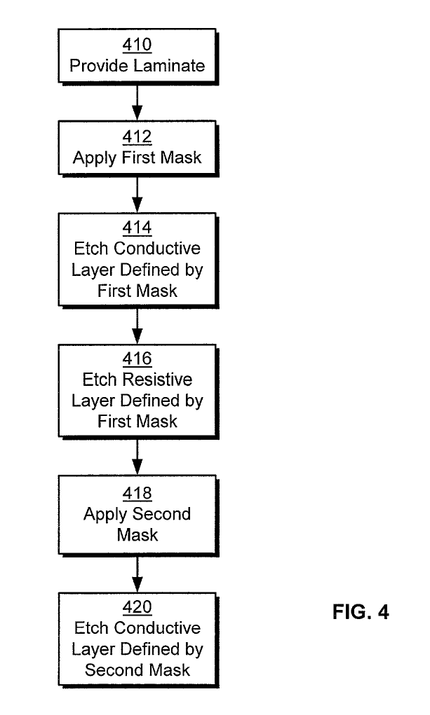

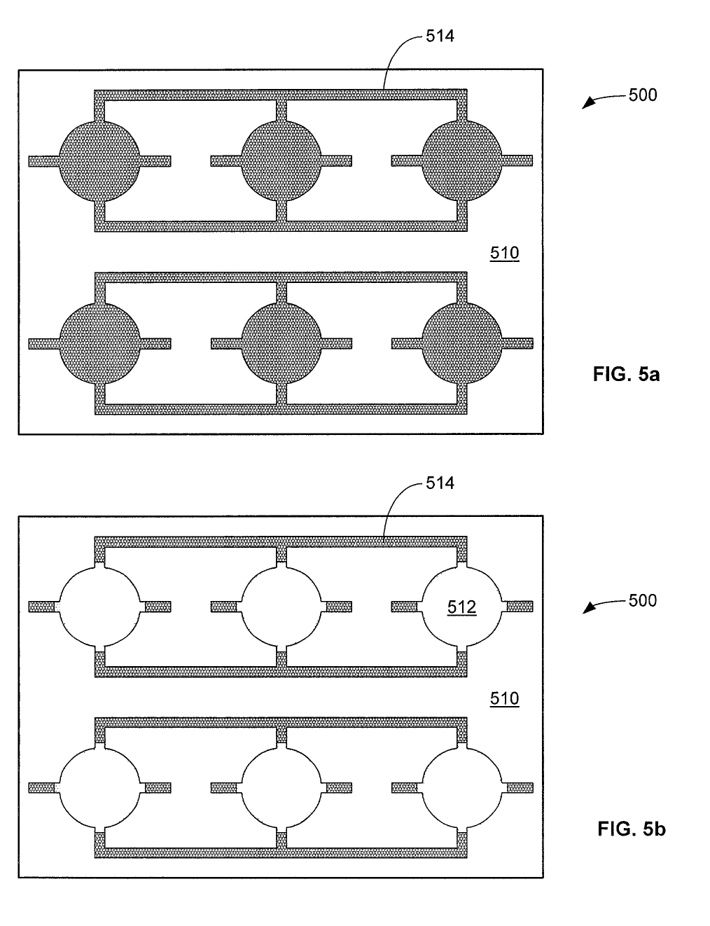

FIG. 4 is a flowchart that illustrates a manufacturing process for fabricating a diagnostic circuit board that includes an array of resistive pads. FIGS. 5a and 5b depict a diagnostic circuit board 500 during different stages of the manufacturing process.

At step 410, a laminate is provided that includes at least three layers: a first layer 510 of insulating material; a second layer 512 of resistive material bonded to the first layer; and a third layer 514 of conductive material bonded to the second layer and forming an outer surface of the circuit board 500.

At step 412, a first mask is applied to the outer surface of the circuit board 500. The first mask defines regions on the circuit board 500 that are resistant to chemical etching. These regions correspond to areas where neither resistive material 512 nor conductive material 514 are to remain on the surface of the circuit board 500 after etching.

At step 414, a first chemical bath is applied to the surface of the circuit board 500. The first chemical bath etches away conductive material 514 not protected by the first mask. A second chemical bath is then applied at step 416. The second chemical bath etches away resistive material 512 not protected by the first mask. At the conclusion of step 416, the surface of the circuit board 500 appears substantially as shown in FIG. 5a. The first mask is then removed.

At step 418, a second mask is applied to the circuit board 500. The second mask defines areas on the surface of the circuit board 500 where conductive material is to be etched away.

At step 420, a chemical bath is applied to the circuit board, and conductive material not protected by the second mask is removed. At the conclusion of step 420, the circuit board 500 appears substantially as shown in FIG. 5b.

The resultant features on the circuit board 500 include an array of resistive pads 110, as well as electrodes and conductive connections between them. The circuit board 500 preferably includes at least one additional layer of conductive material, for example on the back surface of the board 500, for establishing electrical connections among the different resistive pads 110.

In the preferred embodiment, the laminate includes standard Ohmega-Ply® material with a sheet resistivity of 25-ohms/square. Ohmega-Ply® is a thin-film nickel alloy (a resistive layer 512) electrodeposited onto copper foil (a conductive layer 514). Ohmega-Ply® is conventionally used to manufacture buried, thin-film resistors between layers of circuit boards. By bonding Ohmega-Ply® to an insulating layer 510 of FR4, for example, the three layers described above can be realized. We have not previously observed Ohmega-Ply® being used at an outer surface of a circuit board; however, we have found it to be durable material that is highly resistant to scratches and oxidation.

All circuit boards are known to suffer from dimensional errors. To minimize dimensional errors in manufacturing, a direct write tool is used to apply masks to the circuit board 500. Direct write tools are highly accurate lithography instruments that operate by moving a circuit board around a scanned point of light. Direct write tools are manufactured by Carl Zeiss, Inc., having U.S. headquarters in New York, N.Y., and are currently in use for circuit board fabrication by Sanmina Technology Center, of Haverhill, Mass.

Depending upon the accuracy of the manufacturing process, the tabs 122, 124, 126, and 128 can be either enlarged or reduced. In general, the tabs ensure that no conductive material (i.e., copper) comes into direct contact with the body 110 of the resistive pad 100. If copper were to make direct contact with the resistive body 110, the geometry of the body 110 would change, and the ability to predict the location of a pin based on measured impedances would be impaired. Therefore, smaller tabs can be provided when highly accurate manufacturing processes are used. Larger tabs should be used with less accurate processes.

The techniques described herein allow high-speed monitoring of pin-to-pad alignment in automatic test systems. Conventional digital multi-meters normally found within testers can measure hundreds of impedances per second, and conventional relays can switch in under 1 ms. Accordingly, using the techniques described, an array of 100 pins can be tested in under a second. An ATE system can store results for later reference. Different test results can be compared over time, and faults can be diagnosed and predicted.

Alternatives

Having described one embodiment, numerous alternative embodiments or variations can be made. For example, the preferred embodiment provides that four different impedances Z₁-Z₄ be measured to determine the position of a pin relative to a pad. Only two impedances are strictly required, however. By measuring just one of Z₁ and Z₂ and one of Z₃ and Z₄, the distances D_{H} and D_{V} can be determined (See EQ. 3 and 8, for example). The two additional impedances merely compensate for dimensional inaccuracies of the tabs 122, 124, 126, and 128. If these inaccuracies are controlled, two measurements can be eliminated for each pad. Accordingly, the resistive pads 100 would include only two electrodes, one horizontal electrode and one vertical electrode. Providing two electrodes instead of four allows higher packaging density of pads, and simpler circuit boards.

Sometimes it may be desirable to monitor pin-to-pad alignment along one dimension only, for example, in the horizontal dimension. This may arise when pins are physically constrained from moving vertically, but not from moving horizontally. In these instances, two electrodes may be used, spaced apart by approximately 180 degrees, for estimating the position of a pin. Only one electrode is strictly required, however, provided that dimensional inaccuracies of the tab can be controlled.

The preferred embodiment provides that a rigid printed circuit board be used to hold an array of resistive pads. Flexible printed circuit media, such as flex boards, can also be used.

Other types of compressible pins can be used besides spring-loaded pins. For example, the invention can be applied to connections made with small, S-shaped wires called “MicroSprings,” made by FormFactor, Inc., of Livermore, Calif. Other compressible pins not employing conventional springs can also be used.

The embodiment described above applies to compressible pins that make contact with fixed pads. The invention also applies, however, to rigid pins making contact with compressible pads. According to this variation, a compressible circuit board, for example, one made of an elastomeric material, can be used instead of a rigid circuit board, for holding the array of compressible, resistive pads.

In addition, pins have been described as extending from the tester, and pads have been provided on the DIB. This arrangement can obviously be reversed, with pins extending from the DIB and pads on the tester.

The techniques described above can also be used for checking the alignment of pins on subassemblies of a tester. For example, the techniques can be used to check pin alignment on probe towers, before the probe towers are installed within a tester. In addition, the invention is not limited to testers. It can also be used to measure pin alignment on a wide variety of electronic assemblies.

As described above, the resistive pads 100 are substantially round and can be divided into four equal quadrants. Nothing requires this specific shape, however. Pads found in real electronic assemblies assume a wide variety of shapes, and the resistive pads 100 used to check the alignment of pins with these pads should be tailored to match these shapes. As described above, impedances Z₁-Z₄ are measured by forcing an accurate current into each pin and measuring the resultant voltage imposed across the pad. As ready known to the skilled practitioner, however, there is a wide variety of methods for measuring impedance. For example, a simple ohmmeter can be used. Alternatively, a fixed voltage can be imposed between the pin and each electrode of a pad, and the resultant current measured to deduce the impedance.

In addition, impedances need not be measured using a centralized analog instrument within the tester. An external instrument, for example an IEEE-488 bench-top instrument, or a VXI instrument, can be used. Alternatively, each pin of the tester can include a separate instrument for measuring impedance at that pin.

The conventions “left,” “right,” “top,” and “bottom” have been used above to indicate relative orientations of the electrodes and different quadrants of the pads. These are provided as arbitrary designations for reference only.

Each of these alternatives and variations, as well as others, has been contemplated by the inventor and is intended to fall within the scope of the instant invention. It should be understood, therefore, that the foregoing description is by way of example, and the invention should be limited only by the spirit and scope of the appended claims.

What is claimed is:

1. A system for monitoring the alignment of pins with conductive pads at an interface between different portions of an electronic assembly, comprising:
an array of resistive pads adapted to be positioned at the interface in place of the conductive pads, each resistive pad having a substantially uniform sheet resistivity and comprising-
an electrode forming an electrical connection with a portion of the resistive pad,
wherein a pin brought in contact with the resistive pad forms an impedance with the electrode indicative of a location of the pin with respect to the resistive pad.

2. A system as recited in claim 1, wherein the electrode is a first electrode, the impedance is a first impedance, and the portion of the resistive pad is a first portion of the resistive pad, the system further comprising:
a second electrode forming an electrical connection with a second portion of the resistive pad,
wherein the pin brought in contact with the resistive pad forms a second impedance with the second electrode, the second impedance also being indicative of the location of the pin with respect to the resistive pad.

3. A system as recited in claim 1, wherein the array of resistive pads is provided on a printed circuit board.

4. A system as recited in claim 2, wherein the pin brought in contact with each resistive pad is switchably coupled to a first input of an impedance-measuring device.

5. A system as recited in claim 4, wherein the first electrode of each resistive pad is switchably coupled to a second input of the impedance-measuring device.

6. A system as recited in claim 5, wherein the second electrode of each resistive pad is switchably coupled to the second input of the impedance-measuring device.

7. A system as recited in claim 6, wherein the impedance-measuring device comprises a current source for injecting a controlled current from a first node and a voltmeter for measuring a voltage between the first node and a second node.

8. A system as recited in claim 2, wherein-
the first electrode of each resistive pad is coupled to the first electrode of each other resistive pad in the array of resistive pads; and
the second electrode of each resistive pad is coupled to the second electrode of each other resistive pad in the array of resistive pads.

9. A system as recited in claim 2, wherein each of the resistive pads further comprises:
a third electrode forming an electrical connection with a third portion of the resistive pad, and
a fourth electrode forming an electrical connection with a fourth portion of the resistive pad.

10. A system as recited in claim 9, wherein
the third electrode of each resistive pad is switchably coupled to the second input of the impedance measuring device; and
the fourth electrode of each resistive pad is switchably coupled to the second input of the impedance measuring device.

11. A system as recited in claim 10, wherein
the third electrode of each resistive pad is coupled to the third electrode of each other resistive pad in the array of resistive pads; and
the fourth electrode of each resistive pad is coupled to the fourth electrode of each other resistive pad in the array of resistive pads.

12. A system as recited in claim 1, where the electronic assembly includes any of a tester, a prober, a handler, and a probe tower.

13. A system as recited in claim 2, wherein the first and second portions of the resistive pad are first and second of first through fourth substantially evenly divided quadrants of the resistive pad.

14. In a test system having a first portion in which an array of pins is arranged in a predetermined geometrical pattern, and a second portion in which an array of conductive pads is arranged in a matching pattern so that aligned pins of the array of pins contact the conductive pads when the first and second portions are brought together, a system for monitoring the alignment of pins with conductive pads, comprising:
a printed circuit board having an array of resistive pads arranged in the matching pattern and disposed in place of the second portion so that aligned pins of the first portion make contact with the resistive pads, each resistive pad comprising at least one electrode forming an electrical connection with at least one respective region of the resistive pad; and
an impedance measuring device having a first input switchably coupled to each of the plurality of pins and a second input switchably coupled to each at least one electrode of each resistive pad.

15. A method of monitoring the alignment of a plurality of pins arranged in a predetermined geometrical pattern with a plurality of conductive pads arranged in a matching geometrical pattern at an interface between different portions of a test system, comprising the steps of:
(A) installing, in place of the conductive pads, an array of resistive pads arranged in the matching geometrical pattern, so that each resistive pad in the array of resistive pads faces a corresponding one of the plurality of pins;
(B) measuring an impedance between at least one of the plurality of pins and an electrode of the corresponding resistive pad; and
(C) determining, responsive to the impedance measured in step (B), an alignment of said at least one of the plurality of pins with respect to the corresponding pad.

16. A method as recited in claim 15, wherein the impedance is a first impedance and the electrode is a first electrode, and further comprising:
(D) measuring a second impedance between said at least one of the plurality of pins and a second electrode of the corresponding resistive pad.

17. A method as recited in claim 16, wherein each resistive pad comprises first and second portions, the first electrode forming an electrical connection with the first portion and the second electrode forming an electrical connection with the second portion.

18. A method as recited in claim 17, wherein each resistive pad further comprises third and fourth portions, and further comprising the steps of:
measuring a third impedance between each pin and a third electrode of the corresponding resistive pad;
measuring a fourth impedance between each pin and a fourth electrode of the corresponding resistive pad,
wherein the third and fourth electrodes respectively form electrical connections with the third and fourth portions.

19. A method as recited in claim 18, wherein the step (C) of determining the alignment of each pin comprises determining a location of the pin along an axis connecting the first and third electrodes in response to the first and third impedances.

20. A method as recited in claim 19, wherein the step (C) of determining the alignment of each pin further comprises determining a location of the pin along an axis connecting the second and fourth electrodes in response to the second and fourth impedances.

21. A method as recited in claim 15, further comprising repeating steps A-C for each of the plurality of pins.

22. A method of fabricating a printed circuit board for monitoring the alignment of pins with respect to conductive pads at an interface between different portions of a test system, comprising:
(A) providing a laminate including at least first through third consecutive layers, a first layer of insulating material, a second layer of resistive material, and a third layer of conductive material, the third layer forming an outer surface of the printed circuit board;
(B) applying a first mask to the outer surface of the printed circuit board;
(C) etching away portions of conductive material and resistive material to expose regions of insulating material;
(D) applying a second mask to the outer layer of the printed circuit board; and
(E) etching away portions of conductive material left behind in step (C) to form a plurality of resistive pads,
wherein the steps (C) and (E) of etching include forming at least one conduction path that extends from each of the plurality of resistive pads.

23. A method as recited in claim 22, wherein the step (A) of providing a laminate includes gluing a layer of resistive material coated with conductive material to a layer of insulating material.

24. A method as recited in claim 22, wherein the resistive material comprises nickel-phosphorus.

23. A method as recited in claim 22, wherein the laminate comprises copper bonded to a nickel alloy.

25. A method as recited in claim 22, wherein the step E of etching includes removing conductive material around each resistive pad to create at least one tab around and coextensive with the resistive pad.
